(19) United States
(12) Patent Application Publication
(10) Pub. No.: US 2025/0283928 A1
(43) Pub. Date: Sep. 11, 2025

(54) DETECTING FAILED PULSE FROM RF POWER SOURCE

(71) Applicant: ASM IP HOLDING B.V., ALMERE (NL)

(72) Inventor: Imran Ahmed BHUTTA, Moorestown, NJ (US)

(73) Assignee: ASM IP HOLDING B.V., ALMERE (NL)

(21) Appl. No.: 19/068,714

(22) Filed: Mar. 3, 2025

Related U.S. Application Data
(60) Provisional application No. 63/561,391, filed on Mar. 5, 2024.

(51) Int. Cl. G01R 29/08; H01J 37/32; H01L 21/67

(52) U.S. Cl. CPC G01R 29/0878; H01J 37/32146; H01J 37/32183; H01L 21/67253; H01J 2237/24564

(57) ABSTRACT

In one embodiment, an RF power source provides a pulsing RF signal to a plasma chamber, and a first sensor is positioned between the RF power source and the plasma chamber. A control circuit receives pulse information indicative of an intended value of a parameter of the pulsing RF signal, the parameter being a pulsing frequency, a duty cycle, a pulse amplitude, or a pulse shape. The control circuit also receives sensor signals from the first sensor indicative of an actual value of the parameter of the pulsing RF signal. The control circuit then compares a first value, which is derived from the pulse information, to a second value, which is derived from the one or more sensor signals. Based on the comparison, a fault signal is generated indicative of an inconsistency between the intended value and the actual value of the parameter of the pulsing RF signal.

### CROSS REFERENCE TO RELATED APPLICATIONS

The present application claims the benefit of U.S. Provisional Patent Application No. 63/561,391 filed on Mar. 5, 2024, which is incorporated herein by reference in its entirety.

### BACKGROUND

In making semiconductor devices such as microprocessors, memory chips, and another integrated circuits, the semiconductor device fabrication process may use plasma processing at different stages of fabrication. Plasma processing involves energizing a gas mixture by imparting energy to the gas molecules by the introduction of radio frequency (RF) energy into the gas mixture. This gas mixture is typically contained in a vacuum chamber, also called a plasma chamber, and the RF energy is introduced through electrodes or other means in the chamber. In a typical plasma process, the RF generator generates power at the desired RF frequency and power, and this power is transmitted through the RF cables and networks to the plasma chamber. In some embodiments, the RF energy is provided as a pulsing RF signal. But due to various factors such as failure in communication, failure in hardware, or failure in software, the RF power source sometimes does not generate the desired pulsed output. An undetected failed pulse output may adversely affect the semiconductor fabrication process.

### BRIEF SUMMARY

The present disclosure may be directed to a system including an RF power source configured to provide a pulsing RF signal to a plasma chamber; a first sensor; and a control circuit configured to store pulse information indicative of an intended value of a parameter of the pulsing RF signal, wherein the parameter of the pulsing RF signal is a pulsing frequency, a duty cycle, a pulse amplitude, or a pulse shape; receive one or more sensor signals from the first sensor indicative of an actual value of the parameter of the pulsing RF signal; compare a first value derived from the pulse information to a second value derived from the one or more sensor signals; and based on the comparison, generate a fault signal indicative of an inconsistency between the intended value and the actual value of the parameter of the pulsing RF signal.

In another aspect, a method of detecting a fault in an RF pulse being provided by a pulsing RF power source to a plasma chamber is disclosed, the method including a first sensor; and a control circuit configured to store pulse information indicative of an intended value of a parameter of the pulsing RF signal, wherein the parameter of the pulsing RF signal is a pulsing frequency, a duty cycle, a pulse amplitude, or a pulse shape; receive one or more sensor signals from the first sensor indicative of an actual value of the parameter of the pulsing RF signal; compare a first value derived from the pulse information to a second value derived from the one or more sensor signals; and based on the comparison, generate a fault signal indicative of an inconsistency between the intended value and the actual value of the parameter of the pulsing RF signal.

In another aspect, a matching circuit is operably coupled to an RF power source and a plasma chamber, the RF power source providing a pulsing RF signal to a plasma chamber, is disclosed, the matching circuit including a first sensor; and a control circuit configured to store pulse information indicative of an intended value of a parameter of the pulsing RF signal, wherein the parameter of the pulsing RF signal is a pulsing frequency, a duty cycle, a pulse amplitude, or a pulse shape; receive one or more sensor signals from the first sensor indicative of an actual value of the parameter of the pulsing RF signal; compare a first value derived from the pulse information to a second value derived from the one or more sensor signals; and based on the comparison, generate a fault signal indicative of an inconsistency between the intended value and the actual value of the parameter of the pulsing RF signal.

### BRIEF DESCRIPTION OF THE DRAWINGS

The present disclosure will become more fully understood from the detailed description and the accompanying drawings, wherein:

FIG. 1 is a block diagram of an embodiment of a semiconductor processing system.

FIG. 2 is a block diagram of an embodiment of a semiconductor processing system having an L-configuration matching network.

FIG. 3 is a block diagram of an embodiment of a semiconductor processing system having a pi-configuration matching network.

FIG. 4 is a block diagram of a semiconductor processing system according to another embodiment.

FIG. 5 is a flow chart for an exemplary process of detecting a failed pulse output.

FIGS. 6-8 are graphs showing examples of failed pulse outputs.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present inventions. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present invention may be embodied in the form of computer-implemented processes and apparatuses such as processor-based data processing and communication systems or computer systems for practicing those processes. The present invention may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

In the following description, where circuits are shown and described, one of skill in the art will recognize that, for the sake of clarity, not all peripheral circuits or components are shown in the figures or described in the description. Further, the terms “couple” and “operably couple” can refer to a direct or indirect coupling of two components of a circuit.

The following description of the preferred embodiment(s) is merely exemplary in nature and is in no way intended to limit the invention or inventions. The description of illustrative embodiments is intended to be read in connection with the accompanying drawings, which are to be considered part of the entire written description. In the description of the exemplary embodiments disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and other similar terms refer to a relationship wherein structures are secured or attached to one another either directly or indirectly through intervening structures, as well as both movable or rigid attachments or relationships, unless expressly described otherwise. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to an interpretation of “based entirely on.”

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

### Semiconductor Processing System

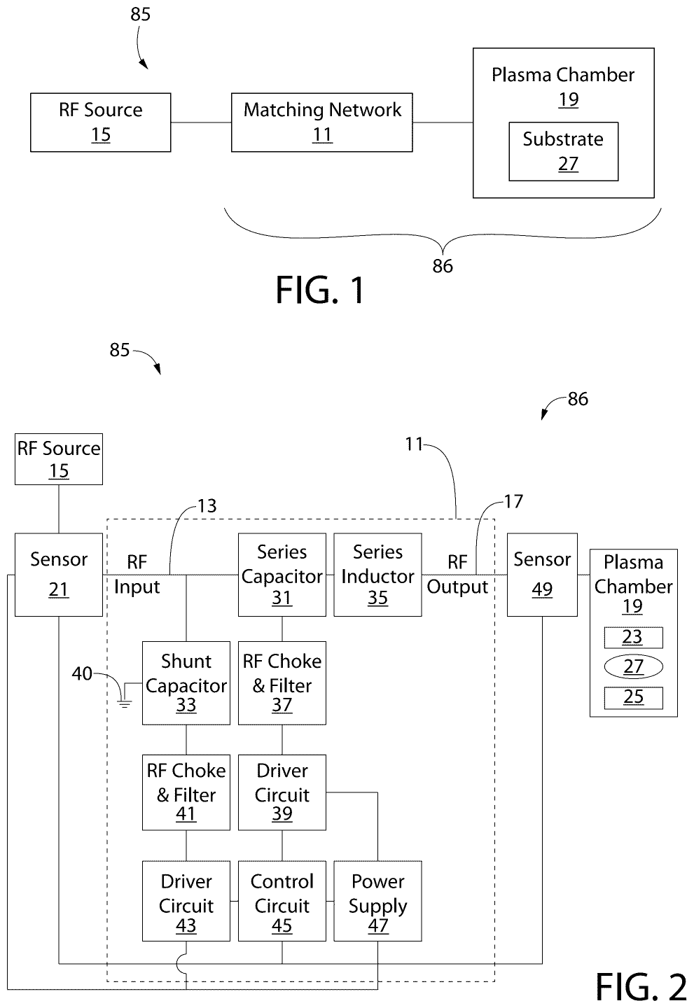

Referring to FIG. 1, a semiconductor device processing system 85 utilizing an RF source 15 is shown. The system 85 includes an RF source 15 and a semiconductor processing tool 86. The semiconductor processing tool 86 includes a matching network 11 and a plasma chamber 19. In other embodiments, the RF source 15 can form part of the semiconductor processing tool.

The semiconductor device can be a microprocessor, a memory chip, or other type of integrated circuit or device. A substrate 27 can be placed in the plasma chamber 19, where the plasma chamber 19 is configured to deposit a material layer onto the substrate 27 or etch a material layer from the substrate 27. Plasma processing involves energizing a gas mixture by imparting energy to the gas molecules by introducing RF energy into the gas mixture. This gas mixture is typically contained in a vacuum chamber (the plasma chamber 19), and the RF energy is typically introduced into the plasma chamber 19 through electrodes. Thus, the plasma can be energized by coupling RF power from an RF source 15 into the plasma chamber 19 to perform deposition or etching.

In a typical plasma process, the RF source 15 is an RF generator that generates power at a radio frequency—which is typically within the range of 3 kHz and 300 GHz—and this power is transmitted through RF cables and networks to the plasma chamber 19. In order to provide efficient transfer of power from the RF source 15 to the plasma chamber 19, an intermediary circuit is used to match the fixed impedance of the RF source 15 with the variable impedance of the plasma chamber 19. Such an intermediary circuit is commonly referred to as an RF impedance matching network, or more simply as an RF matching network. The purpose of the RF matching network 11 is to transform the variable plasma impedance to a value that more closely matches the fixed impedance of the RF source 15. Commonly owned U.S. Publication Nos. 2021/0183623 and 2021/0327684, the disclosures of which are incorporated herein by reference in their entirety, provide examples of such matching networks.

### Matching Network

FIG. 2 is a block diagram of an embodiment of a semiconductor processing system 85 having a processing tool 86 that includes an L-configuration RF impedance matching network 11. As will be discussed in further detail below, the exemplified matching network 11 utilizes electronically variable capacitors (EVCs) for both the shunt variable capacitor 33 and the series variable capacitor 31. It is noted that the invention is not so limited. For example, one of the EVCs (e.g., shunt EVC 33) may be a mechanically variable VVC, or may be replaced with a variable inductor.

The exemplified matching network 11 has an RF input 13 connected to an RF source 15 and an RF output 17 connected to a plasma chamber 19. An RF input sensor 21 can be connected between the RF impedance matching network 11 and the RF source 15. An RF output sensor 49 can be connected between the RF impedance matching network 11 and the plasma chamber 19 so that the RF output from the impedance matching network, and the plasma impedance presented by the plasma chamber 19, may be monitored. Certain embodiments may include only one of the input sensor 21 and the output sensor 49. The functioning of these sensors 21, 49 are described in greater detail below.

As discussed above, the RF impedance matching network 11 serves to help maximize the amount of RF power transferred from the RF source 15 to the plasma chamber 19 by matching the impedance at the RF input 13 to the fixed impedance of the RF source 15. The matching network 11 can consist of a single module within a single housing designed for electrical connection to the RF source 15 and plasma chamber 19. In other embodiments, the components of the matching network 11 can be located in different housings, some components can be outside of the housing, and/or some components can share a housing with a component outside the matching network.

As is known in the art, the plasma within a plasma chamber 19 typically undergoes certain fluctuations outside of operational control so that the impedance presented by the plasma chamber 19 is a variable impedance. Since the variable impedance of the plasma chamber 19 cannot be fully controlled, and an impedance matching network may be used to create an impedance match between the plasma chamber 19 and the RF source 15. Moreover, the impedance of the RF source 15 may be fixed at a set value by the design of the particular RF source 15. Although the fixed impedance of an RF source 15 may undergo minor fluctuations during use, due to, for example, temperature or other environmental variations, the impedance of the RF source 15 is still considered a fixed impedance for purposes of impedance matching because the fluctuations do not significantly vary the fixed impedance from the originally set impedance value. Other types of RF source 15 may be designed so that the impedance of the RF source 15 may be set at the time of, or during, use. The impedance of such types of RF sources 15 is still considered fixed because it may be controlled by a user (or at least controlled by a programmable controller) and the set value of the impedance may be known at any time during operation, thus making the set value effectively a fixed impedance.

The RF source 15 may be an RF generator of a type that is well-known in the art, and generates an RF signal at an appropriate frequency and power for the process performed within the plasma chamber 19. The RF source 15 may be electrically connected to the RF input 13 of the RF impedance matching network 11 using a coaxial cable, which for impedance matching purposes would have the same fixed impedance as the RF source 15.

The plasma chamber 19 includes a first electrode 23 and a second electrode 25, and in processes that are well known in the art, the first and second electrodes 23, 25, in conjunction with appropriate control systems (not shown) and the plasma in the plasma chamber, enable one or both of deposition of materials onto a substrate 27 and etching of materials from the substrate 27.

In the exemplified embodiment, the RF impedance matching network 11 includes a series variable capacitor 31, a shunt variable capacitor 33, and a series inductor 35 to form an ‘L’ type matching network. The shunt variable capacitor 33 is shown shunting to a reference potential, which in this embodiment is ground 40.

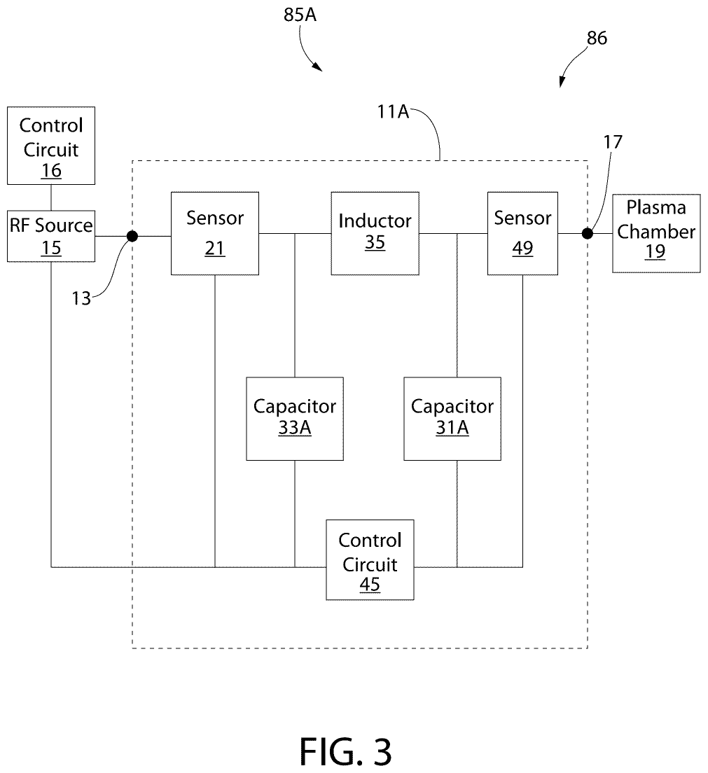

Alternatively, the RF impedance matching network 11 may be configured in other matching network configurations, such as a ‘T’ type configuration or a ‘π’ or ‘pi’ type configuration, as will be shown in FIG. 3. In certain embodiments, the variable capacitors and the switching circuit described below may be included in any configuration appropriate for an RF impedance matching network.

In the exemplified embodiment, and referring to FIG. 2, each of the series variable capacitor 31 and the shunt variable capacitor 33 may be an electronic variable capacitor (EVC), as described in U.S. Pat. No. 7,251,121, the EVC being effectively formed as a capacitor array formed by a plurality of discrete capacitors. The series variable capacitor 31 is coupled in series between the RF input 13 and the RF output 17 (which is also in parallel between the RF source 15 and the plasma chamber 19). The shunt variable capacitor 33 is coupled between the RF input 13 and ground 40. In other configurations, the shunt variable capacitor 33 may be coupled in parallel between the RF output 19 and ground 40. Other configurations may also be implemented without departing from the functionality of an RF matching network. In still other configurations, the shunt variable capacitor 33 may be coupled in parallel between a reference potential and one of the RF input 13 and the RF output 19.

The series variable capacitor 31 is connected to a series RF choke and filter circuit 37 and to a series driver circuit 39. Similarly, the shunt variable capacitor 33 is connected to a shunt RF choke and filter circuit 41 and to a shunt driver circuit 43. Each of the series and shunt driver circuits 39, 43 are connected to a control circuit 45, which is configured with an appropriate processor and/or signal generating circuitry to provide an input signal for controlling the series and shunt driver circuits 39, 43. A power supply 47 is connected to each of the RF input sensor 21, the series driver circuit 39, the shunt driver circuit 43, and the control circuit 45 to provide operational power, at the designed currents and voltages, to each of these components. The voltage levels provided by the power supply 47, and thus the voltage levels employed by each of the RF input sensor 21, the series driver circuit 39, the shunt driver circuit 43, and the control circuit 45 to perform the respective designated tasks, is a matter of design choice. In other embodiments, a variety of electronic components can be used to enable the control circuit 45 to send instructions to the variable capacitors. Further, while the driver circuit 39 and RF choke and filter 37, 41 are shown as separate from the control circuit 45, these components can also be considered as forming part of the control circuit 45.

In the exemplified embodiment, the control circuit 45 includes a processor. The processor may be any type of properly programmed processing device (or collection of two or more processing devices working together), such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable matching network to perform the functions described herein.

With the combination of the series variable capacitor 31 and the shunt variable capacitor 33, the combined impedances of the RF impedance matching network 11 and the plasma chamber 19 may be controlled, using the control circuit 45, the series driver circuit 39, the shunt driver circuit 43, to match, or at least to substantially match, the fixed impedance of the RF source 15.

The control circuit 45 performs various operations and functions for the RF impedance matching network 11, such as receiving multiple inputs from sources such as the RF input sensor 21 and the series and shunt variable capacitors 31, 33, making the calculations necessary to determine changes to the series and shunt variable capacitors 31, 33, and delivering commands to the series and shunt variable capacitors 31, 33 to create the impedance match. The control circuit 45 may be of the type that is commonly used in semiconductor fabrication processes, and therefore known to those of skill in the art. Any differences in the control circuit 45, as compared to control circuits of the prior art, arise in programming differences to account for the speeds at which the RF impedance matching network 11 is able to perform switching of the variable capacitors 31, 33 and impedance matching.

Each of the series and shunt RF choke and filter circuits 37, 41 are configured so that DC signals may pass between the series and shunt driver circuits 39, 43 and the respective series and shunt variable capacitors 31, 33, while at the same time the RF signal from the RF source 15 is blocked to prevent the RF signal from leaking into the outputs of the series and shunt driver circuits 39, 43 and the output of the control circuit 45. The series and shunt RF choke and filter circuits 37, 41 are of a type known to those of skill in the art.

FIG. 3 is a block diagram of an embodiment of a semiconductor processing system 85A having a pi-configuration matching network 11A, as opposed to the L-configuration matching network of FIG. 2. For case of understanding, FIG. 3 omits the RF chokes and filters, driver circuits, and power supplies of FIG. 2. Where FIG. 3 uses reference numbers identical to those of FIG. 2, it is understood that the relevant components can have features similar to those discussed with regard to FIG. 2.

The most significant difference between the L- and pi-configuration is that the L-configuration utilizes a series capacitor 31 and shunt capacitor 33, while the pi-configuration utilizes two shunt capacitors 31A, 33A. Nevertheless, the control circuit can alter the capacitance of these shunt variable capacitors 31A, 33A to cause an impedance match. Each of these shunt variable capacitors 31A, 33A can be an EVC, as discussed above. They can be controlled by a choke, filter, and driver similar to the methods discussed above with respect to FIG. 2.

### Detecting a Failed Pulse From the RF Power Source

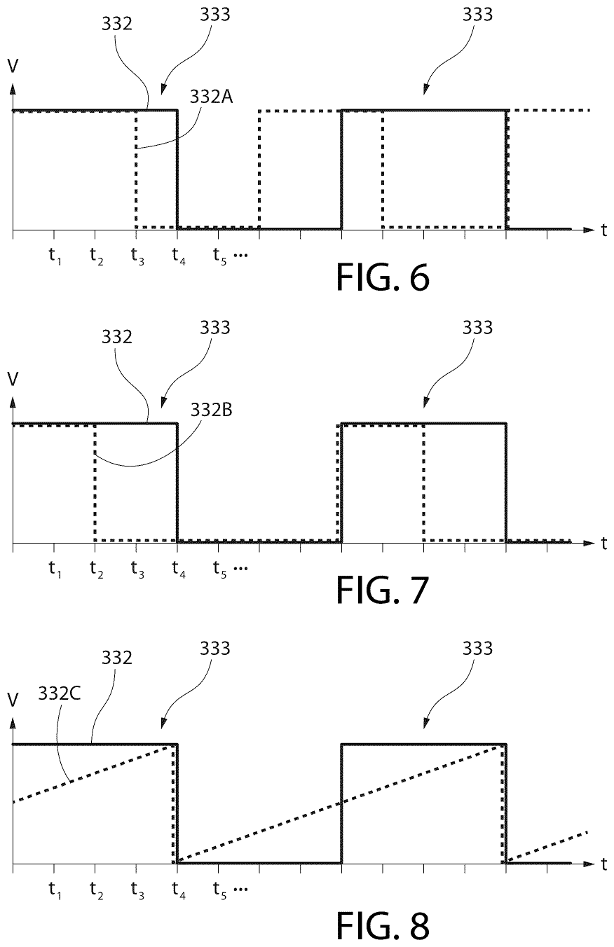

In a semiconductor processing system, the RF power source (such as RF source 15 discussed above) may provide a pulsing RF signal (see, e.g., signal 332 of FIG. 6, discussed below). A pulsing RF source may be distinguished from a continuous wave source, which has an electromagnetic wave of substantially constant amplitude and frequency, or a sine wave. The pulsing RF signal of a pulsing RF source, by contrast, provides cyclically recurring pulse intervals, having a pulse repetition frequency (referred to herein as a pulsing frequency) and a duty cycle (generally defined as a percentage representing the ratio of the pulse ON time to the pulse OFF time). The pulse amplitude or shape may also be defined. The change in the power amplitude level of a pulsing RF signal can vary, and in some circumstances be very frequent (e.g., of the order of a few tens of hundreds of microseconds). In some embodiments, the pulsing RF source may generate a multi-level pulse signal such that there is more than one non-zero pulse level. Regarding multi-level power setpoints and pulsing RF sources in general, commonly-owned U.S. Pat. No. 10,720,309 and U.S. application Ser. No. 18/496,238 are incorporated herein by reference in their entirety.

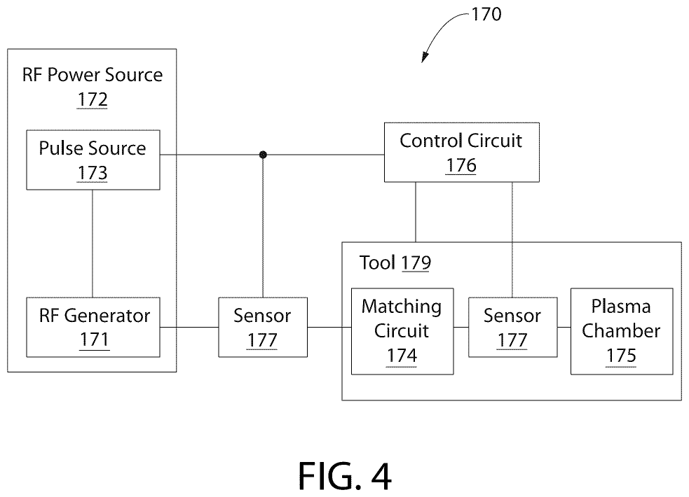

FIG. 4 is a block diagram of a semiconductor processing system according to one embodiment, where the RF power source 172 provides a pulsing RF signal to the semiconductor processing tool 179 and its plasma chamber 175, and a matching circuit 174 is positioned between the source 172 and chamber 175 to provide impedance matching. (See the discussions above for more details on how the matching network(s), control circuit(s), and plasma chamber may operate.)

In this embodiment, the RF power source 172 includes an RF generator 171 and a pulse source 173. In certain embodiments, the pulse source 173 may be separate from (e.g., in a separate enclosure from) the RF generator 171, and the pulse source 173 may transmit pulses to the RF generator 171. In other embodiments, the pulse source 173 may form part of the RF generator 171 or the RF generator itself generates the RF pulse.

The system 170 may include one or more sensors 177 that may sample signals. The exemplified sensors are between the RF power source and the matching circuit 174 (e.g., at an input of the matching circuit or an output of the power source), and between the matching circuit and the plasma chamber (e.g., at an output of the matching circuit or an input of the plasma chamber). The invention, however, is not so limited, as the sensor can be at any location in the system 170, including internal to the matching circuit (see, e.g., sensors 21, 49 of FIG. 3). These sensors may measure any parameter of the pulsing RF signal, including voltage, current, and/or phase. The sensor may have any of the features of sensors discussed herein (e.g., sensor 21 of FIG. 2). The sensors may be, for example, a directional coupler or a voltage-current (VI) and phase sensor.

The system 170 further includes a control circuit 176. This control circuit 176 may have features similar to the control circuits discussed herein, such as control circuit 45 of FIGS. 2 and 3. The control circuit 176 may receive inputs from sources such as the RF power source 172 (or a pulse source 173) and one or more sensors 177, make calculations and other determinations for identifying a failed pulse, and deliver informational signals or commands regarding a failed pulse. The hardware for the control circuit 176 may be of the type of control circuit that is commonly used in semiconductor fabrication processes, and therefore known to those of skill in the art. As an example, the control circuit may include a comparator circuit that can receive both (a) the sampled sensor signal from sensor 177, which indicates what the pulses actually looks like at, and (b) the pulse information from the pulse source 173, which indicates the intended pulse. This comparator could then see, for example, if the actual pulse frequency and/or duty cycles are the same or similar and, if they do not match, trigger a warning or fault. Differences in the control circuit 176, as compared to control circuits of the prior art, may arise in programming differences to enable the pulse-detection functionality discussed herein. In the exemplified embodiment, the control circuit 176 is separate from (and in operable communication with) the tool 179 and the matching circuit 174, but in other embodiments, the control circuit 176 may form part of the tool 179 or part of the matching circuit 174 (such as in FIGS. 2 and 3).

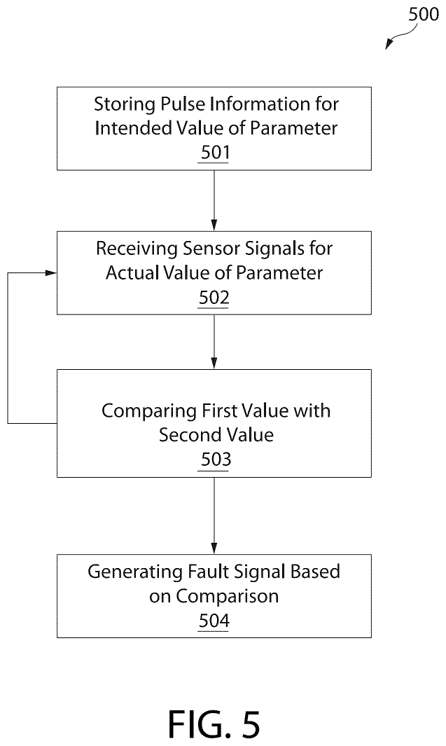

FIG. 5 is a flow chart for an exemplary process 500 of detecting a failed pulse output. In a first operation, the control circuit stores pulse information indicative of an intended value of a parameter of the pulsing RF signal (operation 501). The parameter of the pulsing RF signal may be a pulsing frequency, a duty cycle, a pulse amplitude, a pulse shape, or another parameter relating to the pulsing RF signal. The pulse information may be provided, for example, as a pulse envelope signal that depicts the desired shape of the pulsed RF output, or as data that represents the desired pulsed output. This pulse information may be used by the RF power source to generate the desired pulsed output, and/or may be used by the control circuit (discussed below) as a representation of the desired pulsed output.

In one example, the desired pulse signal has a 5 kHz pulse frequency with 40% duty cycle. When the user sets the system to provide this specific pulse signal, the control circuit 176 can determine the desired pulse ON time should be 80 μs and OFF time should be 120 μs. As the control circuit 176 samples data from the output sensor 177, it can measure for how long the RF signal was ON, and for how long it was OFF, and then calculate the actual generated pulse frequency and duty cycle and compare them to the desired 5 kHz pulse frequency and 40% duty cycle values (and/or compare the ON and OFF times). If the values do not match, a warning or fault may be issued. The amplitude of the detected signal from sensor 177 can also be sampled. If that amplitude is different for one or more pulses (or different from a predetermined value), then it can also warn the system to say that the output pulse was anomalous and did not match the previous pulse amplitudes (or the predetermined value) and this can also trigger a warning or fault.

The pulse information may be received, for example, from the RF power source 172. It may also be received directly from a pulse source 173 separate from the RF generator 171. The pulse source 173 may also provide the pulse information to the RF generator 171, which in turn provides the pulse information to the control circuit 176.

In another operation, the control circuit 176 receives one or more sensor signals from the first sensor 177 indicative of an actual value of the parameter of the pulsing RF signal (operation 502). For example, each of the one or more sensor signals may be indicative of a sensed or measured voltage or current. This sensed voltage or current may be used to determine the actual value of the parameter (e.g., pulsing frequency, a duty cycle, a pulse amplitude, or a pulse shape) of the pulsing RF signal.

In another operation, the control circuit 176 compares (a) a first value that is derived from the pulse information to (b) a second value that is derived from the one or more sensor signals (operation 503). In one embodiment, the first value is the intended value of the parameter (e.g., pulsing frequency, a duty cycle, a pulse amplitude, or a pulse shape) and the second value is the actual value of the parameter. For example, the control circuit compares the intended pulsing frequency and the actual pulsing frequency. In other embodiments, the first value may be any value derived from or based on the pulse information, and the second value may be any value derived from based on from the sensor signals (including a voltage or current value derived from the sensor signals). For example, regarding the first value, the pulse information may comprise data (digital or analog) transmitted via a signal, and this data may be used to derive the first value. Regarding the relationship between the first value and the intended value, the first value may be, for example, a value (e.g., a voltage, current, or phase value) that may be used to determine (e.g., calculate) the intended value, or may be a value derived from the intended value. Similarly, regarding the second value, the sensor signals comprise data (digital or analog), and this data may be used to derive the second value. Regarding the relationship between the second value and the actual value, the second value may be, for example, a value (e.g., a voltage, current, or phase value) that may be used to determine (e.g., calculate) the actual value, or may be a value derived from the actual value.

In another embodiment, the first value is a first range of values, and the comparison of the first and second values comprises a determination that the second value is outside the first range of values. In some embodiments, the intended range of values and/or the first range of values may be predetermined or input by a user. In some embodiments, the intended range of values and/or the first range of values may be calculated (e.g., ±1 or ±5% of an intended value). The level of discrepancy to trigger a warning or fault can vary depending on the type of process.

In another operation, based on the comparison of operation 503, the control circuit generates a fault signal indicative of an inconsistency between the intended value and the actual value of the parameter of the pulsing RF signal (operation 504). As discussed above, this inconsistency may be indicative, for example, that the actual value is outside of an intended range of values. The fault signal may be transmitted, for example, to the semiconductor processing tool. The fault signal may be sent using an industrial communication protocol (e.g., EtherCAT or DeviceNet). The fault signal may also be sent using a hardware-based analog or digital signal indicative of a fault. The invention is not limited to these examples, however, as the fault signal may be any type of signal indicating a fault condition. In response to the fault signal, the system can provide a visual or audible indication of a fault condition, and/or cause an action to address the fault condition.

FIGS. 6-8 are graphs showing examples of failed pulse outputs that may be detected by the disclosed systems and methods. In these examples, the pulses are shown in terms of voltage output over time. In each graph, a first waveform 332 represents the intended pulse signal, which is based on the received pulse information. The second waveform 332A, 332B, 332C represents the actual pulse signal (based on the sensor signals), which has failed pulse outputs. In FIG. 6, the actual RF signal 332A has a frequency that is higher than the frequency of the intended RF signal 332. In FIG. 7, the actual RF signal 332B has a duty cycle that is lower than the duty cycle of the intended RF signal 332. And in FIG. 8, the actual RF signal 332C has a pulse shape that is different from the square wave pulse shape of the intended RF signal 332. In this example, the actual RF signal 332C has a sawtooth shape, but in other examples the actual RF signal may be any shape.

In each graph, the second waveform 332A, 332B, 332C showing the actual pulse output comprises a plurality of pulses 333. The pulses 333 are sampled (and thus a sensor signal is generated) at each of times t₁, t₂, t₃, etc. Thus, for each pulse 333 of the pulsing RF signal, the control circuit repeats the steps of receiving the one or more sensor signals and comparing the first and second values to sample the pulsing RF signal and determine an inconsistency and thus an issue with the actual pulsing RF signal. Note that the pulses 333 may be sampled more or less frequently than as shown. More frequent sampling will generally provide more detailed information on the state of the actual pulsing signal. Note further that the waveforms shown in FIGS. 6-8 may be understood to depict an envelope of the original AC signal, or a DC signal derived from the original AC signal. Further, while FIGS. 6-8 show sampling of the parameter of voltage, as discussed above, other parameters may be sampled, such as current and/or phase.

The above process may be carried out as part of a method of manufacturing a semiconductor. Such a manufacturing method may include placing a substrate in the plasma chamber configured to deposit a material layer onto the substrate or etch a material layer from the substrate; and energizing plasma within the plasma chamber by coupling RF power from the RF source into the plasma chamber to perform a deposition or etching.

While the embodiments of a matching network discussed herein have used L or pi configurations, it is noted that the claimed matching network may be configured in other matching network configurations, such as a ‘T’ type configuration. Unless stated otherwise, the variable capacitors, switching circuits, and methods discussed herein may be used with any configuration appropriate for an RF impedance matching network.

While the embodiments discussed herein use one or more variable capacitors in a matching network to achieve an impedance match, it is noted that any variable reactance element can be used. A variable reactance element can include one or more discrete reactance elements, where a reactance element is a capacitor or inductor or similar reactive device.

This application incorporates by reference in its entirety commonly-owned U.S. Pat No. 10,460,912, U.S. Pub. No. 2021/0327684, U.S. Pub. No. US2021/0327684, and U.S. Pat. No. 10,984,985, and U.S. Pub. No. 2023/0215696.

While the inventions have been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system comprising:
an RF power source configured to provide a pulsing RF signal to a plasma chamber;
a first sensor; and
a control circuit configured to:
store pulse information indicative of an intended value of a parameter of the pulsing RF signal, wherein the parameter of the pulsing RF signal is a pulsing frequency, a duty cycle, or a pulse shape;
receive one or more sensor signals from the first sensor indicative of an actual value of the parameter of the pulsing RF signal;
compare a first value derived from the pulse information to a second value derived from the one or more sensor signals; and
based on the comparison, generate a fault signal indicative of an inconsistency between the intended value and the actual value of the parameter of the pulsing RF signal.

2. The system of claim 1 wherein the first value is the intended value of the parameter and the second value is the actual value of the parameter.

3. The system of claim 2 wherein the control circuit calculates the intended value from the pulse information, and calculates the actual value from voltage or current measurements provided by the sensor signals.

4. The system of claim 1 wherein the first value is a first range of values, and the comparison of the first and second values comprises a determination that the second value is outside the first range of values.

5. The system of claim 1 wherein the control circuit receives the pulse information from the RF power source.

6. The system of claim 5 wherein the RF power source comprises an RF generator and a pulse source external from an RF generator, and the control circuit receives the pulse information from the external pulse source.

7. The system of claim 1 wherein the system further comprises a matching circuit positioned between the RF power source and the plasma chamber, and wherein the first sensor is positioned between the RF power source and the matching circuit, between the matching circuit and the plasma chamber, or internal to the matching circuit.

8. The system of claim 7 wherein the control circuit forms part of the matching circuit.

9. The system of claim 1:
wherein the pulsing RF signal comprises a plurality of pulses; and
wherein, for each pulse of the pulsing RF signal, the control circuit repeats the steps of receiving the one or more sensor signals and comparing the first and second values.

10. The system of claim 1 wherein the plasma chamber is coupled to a semiconductor processing tool, and wherein the fault signal is transmitted to the semiconductor processing tool.

11. A method of detecting a fault in an RF pulse being provided by a pulsing RF power source to a plasma chamber, the method comprising:
storing pulse information indicative of an intended value of a parameter of the pulsing RF signal, wherein the parameter of the pulsing RF signal is a pulsing frequency, a duty cycle, or a pulse shape;
receiving, from a first sensor, one or more sensor signals indicative of an actual value of the parameter of the pulsing RF signal;
comparing a first value based on the pulse information to a second value based on the one or more sensor signals; and
based on the comparison, generating a fault signal indicative of an inconsistency between the intended value and the actual value of the parameter of the pulsing RF signal.

12. The method of claim 11 wherein the first value is the intended value of the parameter and the second value is the actual value of the parameter.

13. The method of claim 12 wherein a control circuit calculates the intended value from the pulse information, and calculates the actual value from voltage or current measurements provided by the sensor signals.

14. The method of claim 11 wherein the first value is a first range of values, and the comparison of the first and second values comprises a determination that the second value is outside the first range of values.

15. The method of claim 11 wherein a control circuit receives the pulse information from the RF power source.

16. The method of claim 15 wherein the RF power source comprises an RF generator and a pulse source external from an RF generator, and the pulse information is received from the external pulse source.

17. The method of claim 11 wherein a matching circuit is positioned between the RF power source and the plasma chamber, and wherein the first sensor is positioned between the RF power source and the matching circuit, between the matching circuit and the plasma chamber, or internal to the matching circuit.

18. The method of claim 11:
wherein the pulsing RF signal comprises a plurality of pulses; and
wherein, for each pulse of the pulsing RF signal, the steps of receiving the one or more sensor signals and comparing the first and second values are repeated.

19. The method of claim 11 wherein the plasma chamber is coupled to a semiconductor processing tool, and wherein the fault signal is transmitted to the semiconductor processing tool.

20. A matching circuit configured to be operably coupled to an RF power source and a plasma chamber, the RF power source providing a pulsing RF signal to a plasma chamber, the matching circuit comprising:
a first sensor; and
a control circuit configured to:
store pulse information indicative of an intended value of a parameter of the pulsing RF signal, wherein the parameter of the pulsing RF signal is a pulsing frequency, a duty cycle, or a pulse shape;
receive one or more sensor signals from the first sensor indicative of an actual value of the parameter of the pulsing RF signal;
compare a first value based on the pulse information to a second value based on the one or more sensor signals; and
based on the comparison, generate a fault signal indicative of an inconsistency between the intended value and the actual value of the parameter of the pulsing RF signal.
